(19) United States
(12) Patent Application Publication
(10) Pub. No.: US 2024/0234513 A9
(43) Pub. Date: Jul. 11, 2024

(54) THREE-TERMINAL BIDIRECTIONAL ENHANCEMENT MODE GaN SWITCH

(71) Applicant: Efficient Power Conversion Corporation, El Segundo, CA (US)

(72) Inventors: Jianjun Cao, Torrance, CA (US); Gordon Stecklein, Van Nuys, CA (US); Edward Lee, Fullerton, CA (US); Shengke Zhang, Irvine, CA (US)

(73) Assignee: Efficient Power Conversion Corporation, El Segundo, CA (US)

(21) Appl. No.: 18/489,098

(22) Filed: Oct. 18, 2023

Related U.S. Application Data
(60) Provisional application No. 63/417,367, filed on Oct. 19, 2022.

(51) Int. Cl. H01L 29/20; H01L 27/06; H01L 29/40; H01L 29/417; H03K 17/687

(52) U.S. Cl. CPC H01L 29/2003; H01L 27/0605; H01L 27/0629; H01L 29/402; H01L 29/41758; H03K 17/687

(57) ABSTRACT

A three-terminal bidirectional GaN FET with a single gate. The device is formed by integrating a single-gate bidirectional GaN FET in parallel with a bidirectional device formed of two back-to-back GaN FETs with a source that is connected to the field plate of the device and does not have a pin-out. Diodes or gate-shorted-to-source FETs are connected between the source without pin-out and the D/S and S/D power terminals of the device. In another embodiment, a single-gate bidirectional GaN FET is provided with diodes or gate-shorted-to-source FETs connected between the substrate and the power terminals of the device.

### CROSS-REFERENCE TO RELATED APPLICATION

This application claims the benefit of U.S. Provisional Application No. 63/417,367, filed Oct. 19, 2022, the disclosure of which is incorporated by reference herein in its entirety.

### BACKGROUND OF THE INVENTION

### 1. Field of the Invention

The present invention relates to a bi-directional GaN field effect transistor (FET) switch.

### 2. Description of the Related Art

A GaN FET is naturally bidirectional—i.e., it conducts current in both directions. However, the voltage blocking capability of a GaN FET is non-symmetric—the drain can block high voltages, while the source can only block low voltages.

Back-to-back GaN FETs with dual gates, such as disclosed in U.S. Pat. No. 8,604,512, have the capability to conduct current and block high voltage equally in either direction. However, the current flowing through the device must flow under two gates (i.e., the current flows under the gate of the first FET and the gate of the second FET), which can undesirably increase the channel resistance (R_{DS(ON)}).

A bidirectional GaN FET with a single gate is disclosed in U.S. Patent Application Publication No. 2023/0111542, the disclosure of which is incorporated by reference herein. The device is formed by integrating a single-gate bidirectional GaN FET in parallel with a bidirectional device formed of two back-to-back GaN FETs with a common source. The single-gate bidirectional GaN FET occupies most of the integrated circuit die, such that the integrated device has a low channel resistance, while also capturing the advantages of a back-to-back bidirectional GaN FET device (i.e., the capability to conduct current and block high voltage equally in either direction).

As shown in FIG. 1A, the bidirectional GaN FET of U.S. Patent Application Publication No. 2023/0111542 has four terminals: two drain terminals D1 and D2, a source terminal S, and a single gate G. As shown in FIG. 1B, the bidirectional GaN FET is formed of two switches, sub-switch #1 (a single GaN FET, with a gate and two D/S terminals) and sub-switch #2 (two back-to-back GaN FETs with a common source S). The D/S terminals of sub-switch #1 serve as either drain or source terminals depending upon the direction of current flow.

It would be desirable to provide a bidirectional GaN FET similar to the prior art bidirectional GaN FET shown in FIGS. 1A and 1B, but with only three terminals, as shown in FIG. 1C, and without any increase in gate leakage current.

### SUMMARY OF THE INVENTION

The present invention achieves the objective noted above by providing a device in which a bidirectional GaN FET is integrated on a single die in parallel with a bidirectional device formed of two back-to-back GaN FETs, but without a source terminal (source “pin-out”) for the back-to-back GaN FETs, and without increased gate leakage current.

More specifically, in some embodiments, the three-terminal bidirectional GaN FET switch of the present invention is formed of two sub-switches connected in parallel. The first sub-switch, which occupies most of the integrated circuit and carries most of the current, comprises a single gate GaN field effect transistor (FET) having first and second power electrodes and a gate centrally located between the first and second power electrodes. The second sub-switch comprises a first GaN FET and a second GaN FET connected in a back-to-back configuration and having a common gate and a source without a pin-out. The gate of the first sub-switch is electrically connected to the common gate of the first and second back-to-back GaN FETs of the second sub-switch to form the three-terminal bidirectional GaN FET with a single gate. The source of the second sub-switch, which has no pin-out, is connected to the field plate. The source of the second sub-switch may also be electrically connected to the substrate, or the single gate of the first sub-switch may be electrically connected to the substrate.

In another embodiment, the three-terminal bidirectional GaN FET switch of the present invention is formed of only the first sub-switch (and not the second sub-switch) of the first embodiment, and comprises first and second power electrodes, a gate centrally located between the first and second power electrodes, and a field plate electrically connected to the substrate.

In yet another embodiment, the three-terminal bidirectional GaN FET switch of the present invention is formed of only the first sub-switch. The gate, which is centrally located between the first and second power electrodes, is electrically connected to the substrate.

The above and other preferred features described herein, including various novel details of implementation and combination of elements, will now be more particularly described with reference to the accompanying drawings and pointed out in the claims. It should be understood that the particular methods and apparatuses are shown by way of illustration only and not as limitations of the claims. As will be understood by those skilled in the art, the principles and features of the teachings herein may be employed in various and numerous embodiments without departing from the scope of the claims.

### BRIEF DESCRIPTION OF THE DRAWINGS

The features, objects, and advantages of the present disclosure will become more apparent from the detailed description set forth below when taken in conjunction with the drawings, in which like reference characters identify correspondingly throughout and wherein:

FIG. 1A shows the symbol for a four terminal bidirectional FET with a single gate.

FIG. 1B is a block diagram, showing the two sub-switches of the bidirectional FET of FIG. 1A.

FIG. 1C shows the symbol for a three-terminal bidirectional FET with a single gate.

FIG. 2 is a cross-sectional view of an embodiment of a bidirectional GaN FET with a single gate.

FIG. 3 is a graphical illustration comparing the gate leakage current of a GaN FET with the field plate shorted to the source against the gate leakage current of a GaN FET with the field plate shorted to the gate.

FIG. 4 is a cross-sectional view of a first embodiment of the three-terminal bidirectional GaN FET switch of the present invention.

FIG. 5 is a cross-sectional view of a second embodiment of the three-terminal bidirectional GaN FET switch of the present invention.

FIG. 6 is a top view of the first and second embodiments of the three-terminal bidirectional GaN FET switch of the present invention.

FIGS. 7A, 7B and 7C show, respectively, a circuit schematic, a cross-sectional view, and a block diagram of the first and second embodiments of the three-terminal bidirectional GaN FET switch of the present invention.

FIG. 8 shows a cross-sectional view of a third embodiment of the three-terminal bidirectional GaN FET switch of the present invention.

FIG. 9 shows a cross-sectional view of a fourth embodiment of the three-terminal bidirectional GaN FET switch of the present invention.

FIG. 10 is a top view of the three-terminal bidirectional switches of FIGS. 8 and 9.

FIG. 11 shows a cross-sectional view of a fifth embodiment of the three-terminal bidirectional GaN FET switch of the present invention.

### DETAILED DESCRIPTION OF THE PREFERRED EMBODIMENTS

In the following detailed description, reference is made to certain embodiments. These embodiments are described with sufficient detail to enable those skilled in the art to practice them. It is to be understood that other embodiments may be employed, and that various structural, logical, and electrical changes may be made.

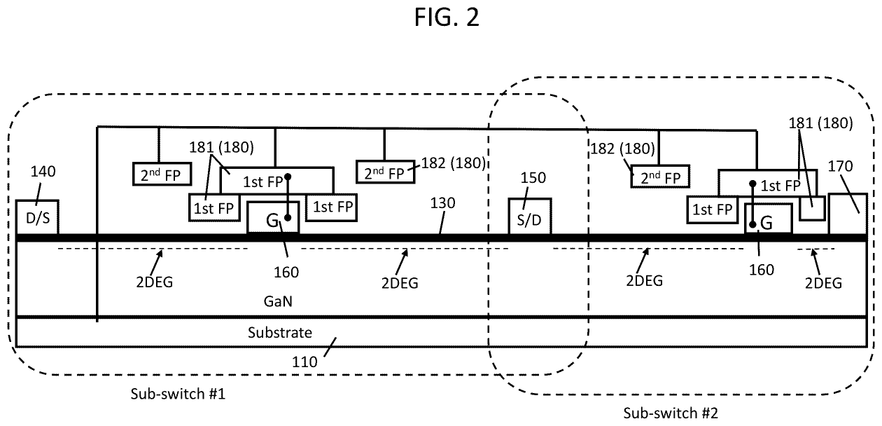

FIG. 2 shows an embodiment of a bidirectional GaN FET with a single gate, disclosed in U.S. Patent Application Publication No. 2023/0111542, which can be a three-terminal bidirectional GaN FET switch if source 170 is provided without a pin-out as shown. This embodiment, however, has a higher gate leakage I_{gss} than other embodiments of the single gate bidirectional GaN FET switch disclosed in U.S. Patent Application Publication No. 2023/0111542. The present invention, as described and claimed below, provides various modifications of this embodiment from a four-terminal to a three-terminal bidirectional single gate GaN FET, but without increased gate leakage current.

Conventional FET transistors have field plates in the following configurations:
1) At gate potential
2) At source potential
3) First field plate at gate potential; other field plates at source potential.
The source and gate potentials are supplied by an external gate driver.

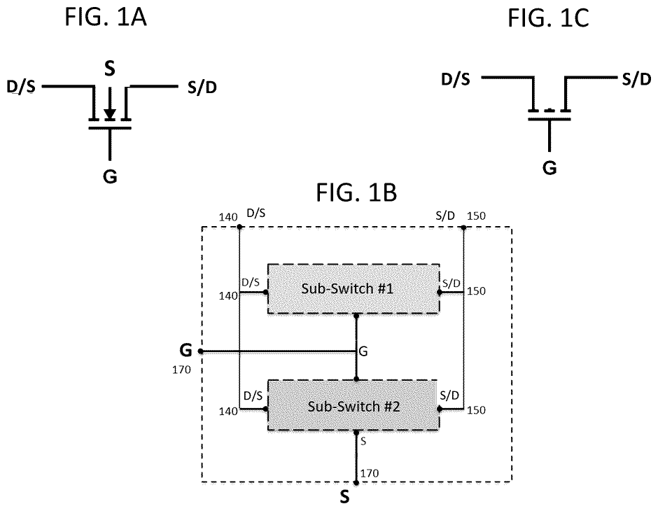

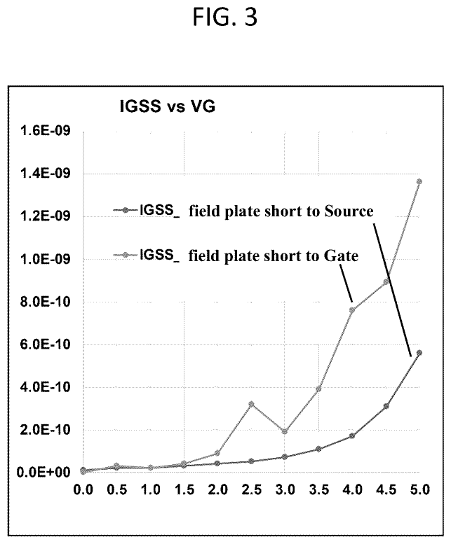

The present invention, directed to a three-terminal bidirectional GaN FET with a single gate, is based on the following considerations:
A three-terminal bidirectional switch has two power terminals, D/S and S/D, and a gate. A three-terminal bidirectional switch does not have a source. Compare FIG. 1A (four-terminal bidirectional switch) and FIG. 1C (three-terminal bidirectional switch).
Neither the substrate nor the field plate can be electrically connected to the either of the power terminals (S/D and D/S).
In a GaN FET, undesirable gate leakage is lower if the field plate is connected to the source, rather the gate. See FIG. 3.

The present invention achieves the objective of providing a three-terminal bidirectional switch with low gate leakage, as more fully described below, in which: (1) the field plate is connected to the source of the three-terminal bidirectional switch shown in FIG. 2, without a source pin-out, or (2) the bidirectional switch does not include a sub-switch #2, i.e., the bidirectional switch is provided without two back-to-back GaN FETs. In both versions (1) and (2) of the three-terminal bidirectional switch of the present invention, the substrate may optionally be shorted to the gate to reduce the on-resistance of the device.

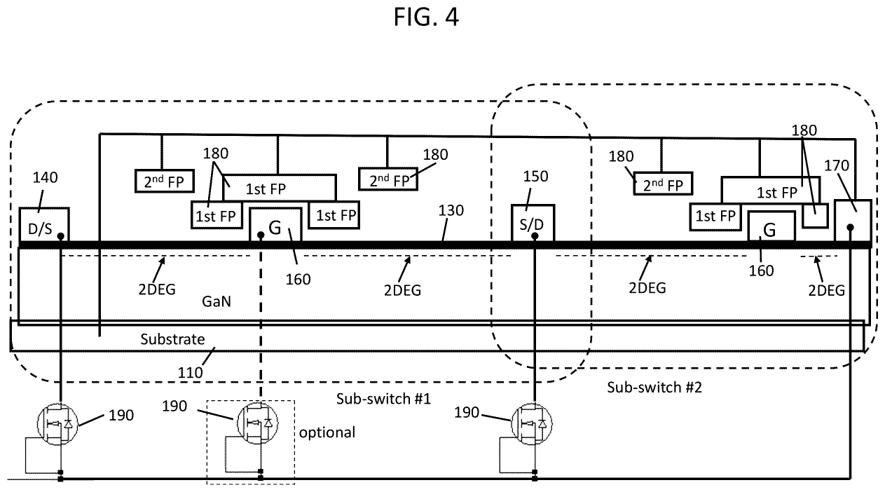

FIG. 4 shows a cross-sectional view of a first embodiment of the present invention in which the field plate is connected to the source of a three-terminal bidirectional switch shown in FIG. 2, without a source pin-out. As shown in FIG. 4, the substrate 110 and the field plates 180 are shorted to the source 170. A diode or gate-shorted-to-source FET 190 (which acts as a diode by conduction through the body diode) is connected between source 170 and drain/source (D/S) 140 and between source 170 and source/drain (S/D) 150 (designated D/S or S/D, because each power terminal serves as either a drain D or a source S depending on the direction of current flow). As a result, source 170 (and the connected field plate 180) is at a potential which is less than the voltage drop V_{D} (of the diode or gate-shorted-to-source FET 190)+the lowest of the voltages of D/S 140 and S/D 150. An optional diode or a gate-shorted-to-source FET 190 may be connected between source 170 and gate 160, as shown in dashed lines, in which case source 170 is at a potential which is less than V_{D}+the lowest of the voltages of D/S 140, S/D 150, and gate 160.

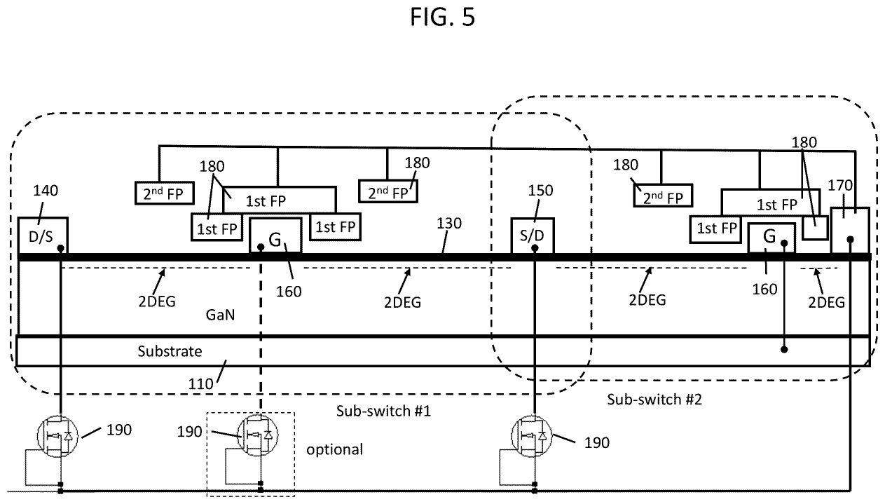

FIG. 5 is a cross-sectional view of a second embodiment of the present invention which is similar to the first embodiment of FIG. 4, but with the substrate 110 shorted to gate 160, which advantageously reduces the on-resistance of the device.

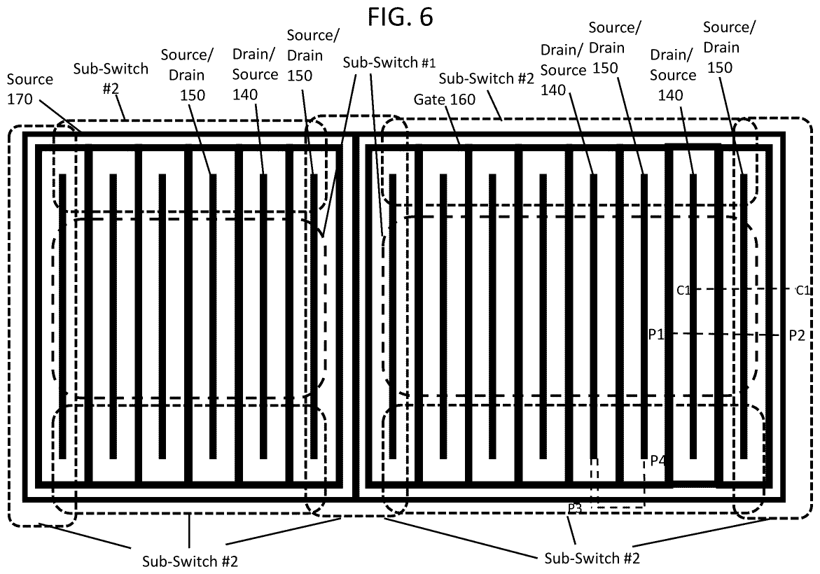

FIG. 6 is a top view of the three-terminal bidirectional switches of FIGS. 4 and 5. As shown in FIGS. 4, 5 and 6, along the channel between ohmic power electrodes D/S 140 and S/D 150 of sub-switch #1, there is only one gate. Accordingly, the channel resistance of sub-switch #1, which occupies most of the die, is reduced as compared to a bidirectional switch which has two gates.

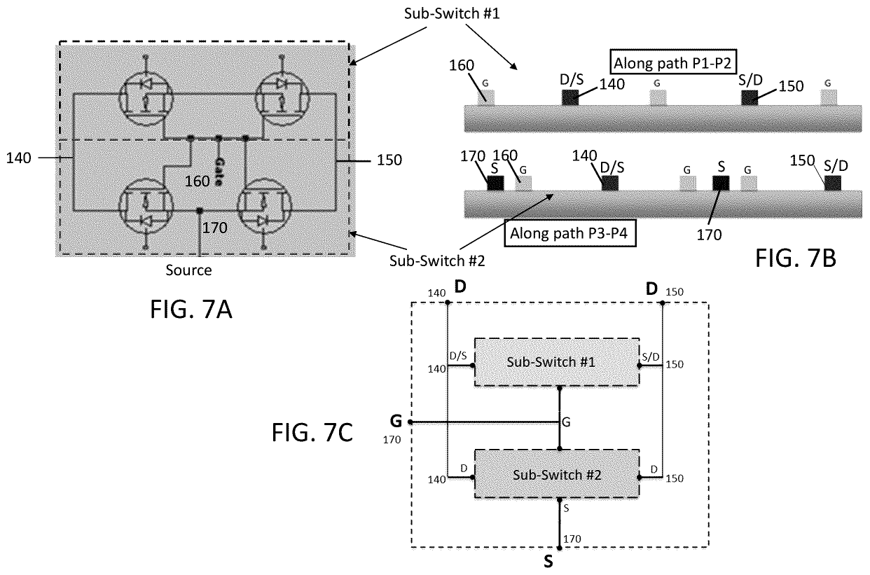

As shown in the equivalent circuit of FIG. 7A and the corresponding block diagram of FIG. 7C, sub-switches #1 and #2 are connected in parallel with respect to power electrodes 140 and 150. The upper portion of FIG. 7B is a cross-sectional view of the first sub-switch along the path P1-P2 as marked in FIG. 6, which shows that, between the first ohmic power electrode 140 and the second ohmic power electrode 150, sub-switch #1 has a source-gate-drain (S-G-D) or drain-gate-source (D-G-S) configuration, depending upon the direction of current flow. The lower portion of FIG. 7B is a cross-sectional view a schematic illustration of sub-switch #2 along the path P3-P4 marked in FIG. 6, which shows that sub-switch #2 has a drain/source-gate-source-gate-source/drain (D/S-G-S-G-S/D) configuration between the first ohmic power electrode 140 and the second ohmic power electrode 150, i.e., back-to-back FETs with a common source.

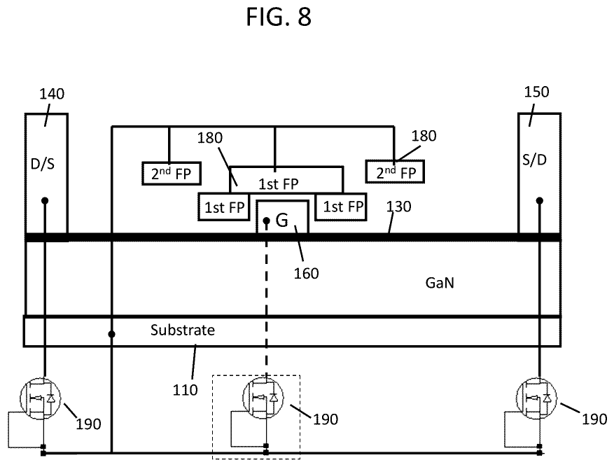

FIG. 8 shows a cross-sectional view of a third embodiment of the present invention, which is a three-terminal bidirectional switch without sub-switch #2. In this embodiment of the invention, the field plates 180 are shorted to the substrate 110. Transistors 190 (preferably GaN FETs as shown), each having gate-shorted-to-source, are connected respectively between the field plates 180/substrate 110 and the three terminals of the device, i.e., the power electrodes (i.e., drain/source (D/S) 140 and source/drain (S/D)) and the gate 160. Thus, the field plates 180 and the substrate 110 are at a potential which is less than V_{D}+the lowest of the voltages of gate 160, D/S 140 and S/D 150.

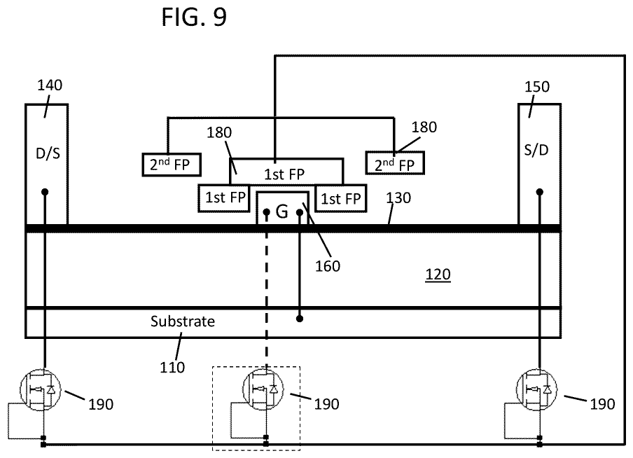

FIG. 9 shows a cross-sectional view of a fourth embodiment of the present invention similar to the third embodiment, but with the substrate 110 not connected to the field plate 180 and instead shorted to gate 160, which advantageously reduces the on-resistance of the device. In this embodiment, diodes or FETs 190, each having a gate shorted to source, are connected between the field plate 180 and each of the power electrodes 140 and 150 (i.e., drain/source (D/S) 140 and source/drain (S/D) 150). Thus, the field plates are at a potential which is less than V_{D}+the lowest of the voltages of D/S 140 and S/D 150. A diode or gate-shorted-to-source FET 190 is optionally connected between the field plate 180 and the gate 160. The substrate is shorted to the gate, which reduces on-resistance.

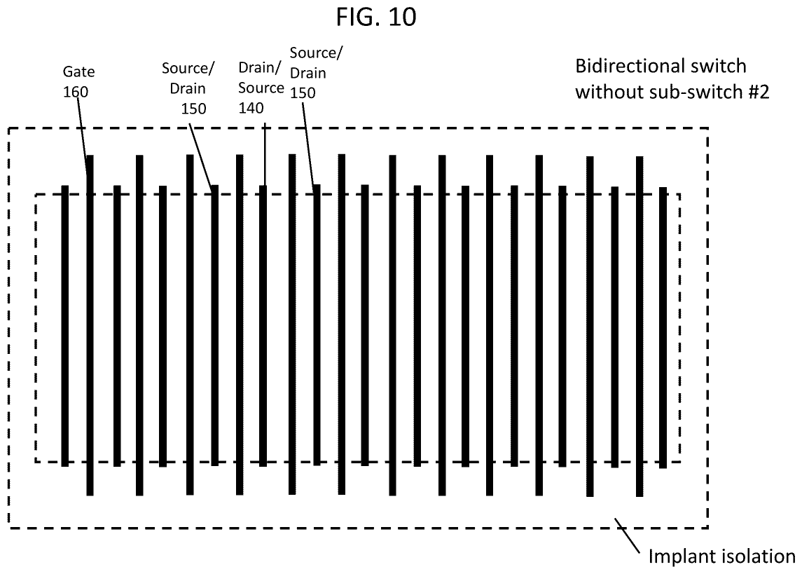

FIG. 10 is a top view of the three-terminal bidirectional switches of FIGS. 8 and 9. As shown in FIG. 10, along the channel between ohmic power electrodes D/S 140 and S/D 150, there is only one gate 160. Accordingly, the channel resistance of the single gate bidirectional switch of the third and fourth embodiments of the invention, is reduced as compared to a bidirectional switch which has two gates.

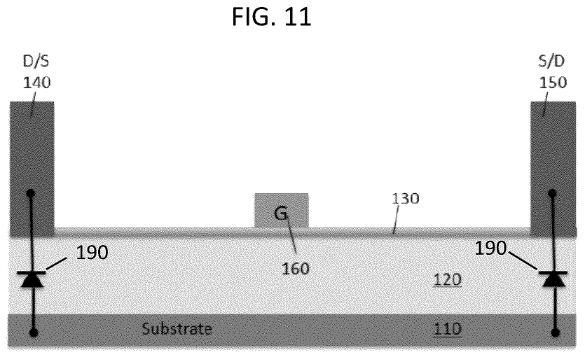

FIG. 11 shows a fifth embodiment of the present invention—a three-terminal bidirectional switch without sub-switch #2 and without a field plate. In this embodiment of the invention, the diodes or gate-to-source-shorted GaN FETs 190 are connected respectively between the substrate 110 and the power electrodes D/S 140 and S/D 150. Thus, the substrate 110 is at a potential which is less than V_{D}+the lowest of the voltages of D/S 140 and S/D 150.

The above description and drawings are only to be considered illustrative of specific embodiments, which achieve the features and advantages described herein. Modifications and substitutions to specific process conditions can be made. Accordingly, the embodiments of the invention are not considered as being limited by the foregoing description and drawings.

What is claimed is:

1. A three-terminal bidirectional GaN FET switch with a single gate, comprising:
a first sub-switch, a second sub-switch connected in parallel with the first sub-switch, and a field plate, wherein:
the first sub-switch comprises a single gate GaN field effect transistor (FET) having first and second power electrodes and a gate centrally located between the first and second power electrodes;
the second sub-switch comprises a first GaN FET and a second GaN FET connected in a back-to-back configuration and having a common gate and a source without a pin-out;
the gate of the first sub-switch is electrically connected to the common gate of the first and second back-to-back GaN FETs of the second sub-switch to form the three-terminal bidirectional GaN FET with a single gate; and
the source without a pin-out of the second sub-switch is connected to the field plate.

2. The three-terminal bidirectional GaN FET switch of claim 1, wherein the three-terminal bidirectional GaN FET switch is formed on a substrate, and the source of the second sub-switch without a pin-out is electrically connected to the substrate.

3. The three-terminal bidirectional GaN FET switch of claim 1, further comprising respective diodes or gate-to-source connected FETs electrically connected between the source without pin-out of the second sub-switch and (i) the first power electrode of the first sub-switch; (ii) the second power electrode of the first sub-switch.

4. The three-terminal bidirectional GaN FET switch of claim 3, further comprising a diode or gate-to-source connected FET electrically connected between the source without pin-out of the second sub-switch and the gate of the first sub-switch.

5. The three-terminal bidirectional GaN FET switch of claim 1, wherein the three-terminal bidirectional GaN FET switch is formed on a substrate, and the gate of the single gate GaN FET of the first sub-switch is electrically connected to the substrate.

6. The three-terminal bidirectional GaN FET switch of claim 1, wherein the first sub-switch and the second sub-switch are integrated on a single die.

7. A three-terminal bidirectional GaN FET switch with a single gate, comprising:
first and second power electrodes;
a gate centrally located between the first and second power electrodes; and
a field plate;
wherein the three-terminal bidirectional GaN FET switch is formed on a substrate, and the field plate is electrically connected to the substrate.

8. The three-terminal bidirectional GaN FET switch of claim 7, further comprising respective diodes or gate-to-source connected FETs electrically connected between the substrate and (i) the first power electrode; and (ii) the second power electrode.

9. The three-terminal bidirectional GaN FET switch of claim 8, further comprising a diode or gate-to-source connected FET electrically connected between the substrate and the gate.

10. A three-terminal bidirectional GaN FET switch with a single gate, comprising:
first and second power electrodes;
a gate centrally located between the first and second power electrodes; and
a field plate;
wherein the three-terminal bidirectional GaN FET switch is formed on a substrate, the gate is electrically connected to the substrate, and respective diodes or gate-to-source connected FETs are electrically connected between the field plate and (i) the first power electrode; and (ii) the second power electrode.

11. The three-terminal bidirectional GaN FET switch of claim 10, further comprising a diode or gate-to-source connected FET electrically connected between the substrate and the gate.

12. A three-terminal bidirectional GaN FET switch with a single gate, comprising:
first and second power electrodes;
a gate centrally located between the first and second power electrodes;
wherein the three-terminal bidirectional GaN FET switch is formed on a substrate; and
respective diodes or gate-to-source connected FETs are electrically connected between the substrate and (i) the first power electrode; and (ii) the second power electrode.
